(19) United States
(12) Patent Application Publication
(10) Pub. No.: US 2017/0361719 A1
(43) Pub. Date: Dec. 21, 2017

(54) Securized and portable electric vehicle charger

(71) Applicants: Serge Doucet, Quebec (CA); Hans Tremblay, L'Ancienne-Lorette (CA)

(72) Inventors: Serge Doucet, Quebec (CA); Hans Tremblay, L'Ancienne-Lorette (CA)

(21) Appl. No.: 15/187,749

(22) Filed: Jun. 20, 2016

(51) Int. Cl. B60L 11/18; H01B 7/08; H01B 9/00; H02J 7/00; G01R 31/02

(52) U.S. Cl. CPC B60L 11/1818; H02J 7/0027; H02J 7/0045; G01R 31/026; H01B 9/006; H01B 7/08; H02J 2007/0096

(57) ABSTRACT

An electric vehicle supply equipment (EVSE) having ability to charge electric vehicle from indoor located 208-240V outlets. The EVSE comprises a flattened armored cable to securely transmit electrical power to outdoor location from indoor located electrical source. In the preferred embodiment, the flattened armored section acts as EVSE anchoring system which providing ease of installation when temporary electric vehicle recharging is required. The EVSE has ability to disconnect electrical power passing through the flat armored cable in case of non proper conditions or if any electrical hazard occurs. A further embodiment comprises a flexible version of flat cable. To enhance its electrical safety, flat wire conductor comprising damage sensor is used to improve the electrical safety. The EVSE may validate flat wire physical integrity before applying electrical power to the flattened flexible cable.

### BACKGROUND OF THE INVENTION

### 1) Field of the Invention

The present invention is related to electric vehicle supply equipment (EVSE). It mainly addresses the problem of deep recharging need after mid or long distance travel of electric vehicle to destination site.

### 2) Description of the Prior Art

Different types of EVSE are commercially available. They are mainly divided in three subcategories depending on their corresponding output power.

The first category consists of Level 1 chargers which are portable lightweight units pluggable on standard 110-120 V volts outlets. Their output power is typically less than 2 kW. They are generally plugged on an outdoor located 110-120 V outlet. That kind of charger is mainly relevant for hybrid rechargeable electric vehicle due to their relatively small capacity battery pack. These cars have battery pack capacity of less than 20 kWh. So the Level 1 chargers are able to fully recharge the battery pack overnight. However, the use of Level 1 chargers is less useful for electric vehicles (EV) with ranges of 100 km and over. Since these vehicles have larger capacity battery packs, the charging time required for complete recharge could take up to 40 hours for some models when recharged with Level 1 chargers.

Level 2 chargers are mostly powered by 208-240V circuits with current varying from 24 A to 40 A. Level 2 chargers are most often permanently installed and hard wired at the EV owner residence parking space. Level 2 EVSE are also available at specific public locations.

Some Level 2 chargers are portable but they still require 208-240V outlets which are closely accessible to the parking space, such as a welder outlet in a garage or one specifically installed outdoor. These chargers are the minimal requirement for EV battery pack overnight recharging but their actual form and structure is not appropriate for temporary installation.

The Society of Automotive Engineer (SAE) developed the SAE J1772 standard which covers the connector mechanical configuration and signal communication protocol between the EV and the EVSE.

The Level 1 and Level 2 charger comprise control electronic to energize the EV supply cable only when physical connection is properly made on the EV and after initiating communication with the EV like registered in the SAE J1772 standard. These control electronics are always installed in protected outdoor located enclosures and in close proximity to the EV parking space.

The third category is comprised of high voltage and continuous current super chargers. These commercial chargers require special installation and cannot be installed at the EV owner residence.

U.S. Patent Application US2012/0206100 to Brown et al. discloses plug and cord versions of level 1 and level 2 EVSE which introduces a pluggable version of EVSE in which a specific ground monitor is added to the typical features covered by the SAE J1772 standard to produce a safer version of a pluggable EVSE. The plug and cord benefits mentioned by the inventors is the flexibility and speed of installation. The EV owner can do the installation of the dedicated outlet before delivery of the EV or the EVSE and he can easily replace its EVSE if it is no longer compatible with a later acquired EV. These EVSE are outdoor installed and requires outdoor located outlet. Level 1 version may be easily installed in majority of residence parking space due to 110-120 V outlet availability. However, level 2 versions lose this benefit due to its 208-240V outlet requirement.

In U.S. Pat. No. 8,558,504 and U.S. Patent Application US2011/0169447, by Brown et al. disclose similar systems has described in U.S. Patent Application US2012/0206100 that specifically claim a timer and an integrated recess in the housing to hold the EV charging connector. These modified EVSE provides additional functionalities but their level 2 version are still suffering from disadvantage of requiring outdoor located outlet availability.

In the EV community, EV owners face the problem of not having access to an outdoor located 208-240 V outlet at destination when they travel to visit family or friends. Many of them simply use a standard welder extension cord connected to an indoor located 208-240 V outlet and then pass the female plug outdoor via a housing opening (door or window) to connect to the outdoor located portable EVSE to charge the EV during their stay. That kind of installation is risky because the outdoor located female plug is not fixed on an exterior wall. They are simply laid on the ground, which represent an electrical hazard due to the absence of electrical disconnection means in case of ground fault at the plug location. Another aspect is the inconvenience of passing a large cable through a housing opening. In fact, the window or door in which the cable is passing through cannot be properly closed while the EVSE is supplied by the extension cord. Considering the many hours of charging time, this means that the housing opening has to stay open for a long period of time leading to potential loss of heat/cool and lack of home security.

In Chinese Patent Application 203311878U by He et al. a flat arrangement of round wires is proposed as an EV charging cable. That kind of cable is obviously flatter than a standard round cable but its thickness may still be too large to ensure correct housing opening closure. Even by using such a cable, electrical safety will continue to be an issue.

U.S. Pat. No. 8,604,343 to Nixon-Lane discloses an electrical power cord with flattened and flexible section which can be placed in the frame of closed window. This invention is mainly addressing small appliance applications and does not incorporates specific electrical safety features to validate the housing opening crossing section before and after the electrification of the flattened section. The flattened section is not especially designed to favor ground fault protection in case of flat cable damage and there is no smart electronic system which validates the cable's integrity before electrifying the flattened section and the outdoor located system. The flattened section of this invention is not especially designed to provide holding and safe anchoring capability which can hold indoor/outdoor various components.

### SUMMARY OF THE INVENTION

The main objective of the present invention is to provide portable Level 2 EVSE which can be easily installed in a housing opening. The invention is designed to provide ease of use and also offer a maximum of electrical protection with safety features. It can be easily installed by an untrained person without need of technical assistance. The invention gets its electrical power from an indoor located 208-240 V outlet.

The invention includes a specially designed protected flat cable assembly which is used to makes the indoor/outdoor connection hence providing the ability to connect the electric vehicle (EV) to an indoor located electrical outlet. In the preferred embodiment, the flat cable is protected from hazardous damage by a metallic armoring which ensures flat wires assembly physical shielding and electrification protection. The proposed invention also includes disconnection means and control electronic located indoor when powered by indoor located outlet. That reduces the electrical risk related to crossing the housing opening. These indoor located disconnection means add a second level of electrical safety by validating the indoor to outdoor component electrical integrity and EV connection before energizing the housing opening crossing component circuit.

The prior art of EVSE obviously includes electrical protections related to ground fault or ground monitoring. These protections are located in a single enclosure before the end cable connected to the EV plug. However, there is no specific prior art related to powering EVSE from an indoor located outlet and to managing the electrical protections needed to safely cross the housing opening.

Even if the proposed invention offer ease of use for temporary installation powered by indoor located outlet, they can still be use has typical EVSE system installed outdoor. So the proposed invention may be installed on outdoor wall by the uses of specially designed EVSE holding enclosure and be powered by especially outdoor installed 208-240 V outlet. But when required, it can be easily remove from this holding enclosure to be used at destination site by using its capability of being temporary installed and powered by indoor located outlet.

### BRIEF DESCRIPTION OF THE DRAWINGS

FIG. 1 is a pluggable version of EVSE as proposed by U.S. Patent Application US2012/0206100 by Brown et al. which requires outdoor located outlet.

FIG. 2 is another pluggable version of EVSE as proposed in U.S. Pat. No. 8,558,504 and U.S. Patent Application US2011/0169447 by Brown et al.

FIG. 3 is a cross section of flattened cable as proposed by Patent Application 203311878U by He et al.

FIG. 4 is a small appliance extension cord which comprising flattened section to be installed in closed window as proposed in U.S. Pat. No. 8,604,343 by Nixon-Lane.

FIG. 5 illustrates the entire system of the preferred embodiment of the invention installed on the upper horizontal door edge.

FIG. 6 is a close up view of the preferred embodiment of the invention shown in FIG. 5.

FIG. 7 is detailed description of the preferred embodiment indoor located EVSE control enclosure assembly.

FIG. 8 is a detailed description of the preferred embodiment of the outdoor located secondary enclosure assembly.

FIG. 9A illustrates the preferred embodiment of the flat cable assembly.

FIG. 9B is an exploded view of the preferred embodiment of the flat cable assembly.

FIG. 10 illustrates the preferred embodiment of flat wire assembly.

FIG. 11A illustrates a sectional view of the flat wire assembly shown in FIG. 10.

FIG. 11B illustrates a sectional view of the flat wire assembly having circular live electrical conductor.

FIG. 12A illustrates one embodiment of the invention which having flexible embodiment of flat cable assembly in compressed form.

FIG. 12B illustrates same embodiment of the invention shown in FIG. 12A which having flexible embodiment of flat cable assembly in expanded form.

FIG. 13 illustrates the sectional view of one embodiment of flexible flat cable assembly shown in FIG. 12A and FIG. 12B.

FIG. 14A illustrates a sectional view of an embodiment of flat wire assembly having additional flat ground electrical conductors.

FIG. 14B illustrates an exploded view of the sectional view of the embodiment of flat wire assembly shown in FIG. 14A.

FIG. 15A illustrates a sectional view of an embodiment of flat wire assembly having additional flat ground electrical conductor and electrical isolation layer.

FIG. 15B illustrates an exploded view of the sectional view of the embodiment of flat wire assembly shown in FIG. 15A.

FIG. 16A illustrates a sectional view of an embodiment of flat wire assembly having additional flat ground electrical conductor, electrical isolation layer and mechanical damage sensor layer with additional electrical isolation layer.

FIG. 16B illustrates an exploded view of the sectional view of the embodiment of flat wire assembly shown in FIG. 16A.

FIG. 17 is a bloc diagram of the electrical circuit connection of the embodiment of flat wire assembly having the mechanical damage sensor.

FIG. 18A illustrates another embodiment of the invention where indoor and outdoor enclosures are held by upper straps and flat cable assembly is passing on the vertical side edge of the house door.

FIG. 18B is a close up view of the embodiment of the invention shown in FIG. 18A.

FIG. 19A illustrates a holding enclosure used to install inside the invention for daily use at the EV owner parking location.

FIG. 19B illustrates the holding enclosure with its front panel opened.

FIG. 20 illustrates one modified embodiment of the invention which can be combined to a state of the art portable EVSE.

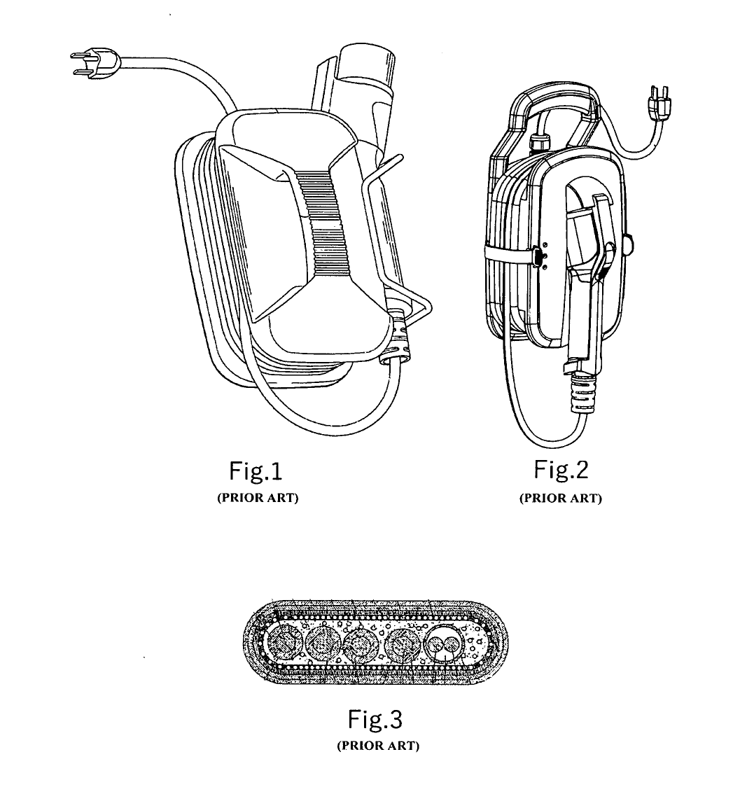

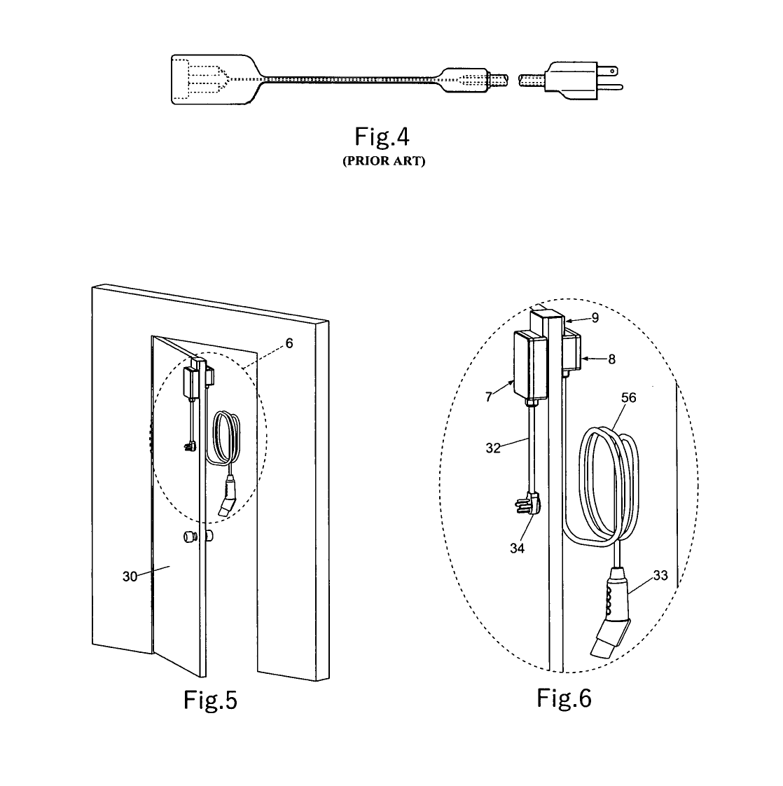

### DETAILED DESCRIPTION

The charger according to the present invention has the ability to be transportable and can be used to charge an EV from an indoor located electrical outlet. The preferred embodiment of the invention is especially designed to be installed on the top edge of standard housing door but other embodiment can be especially designed for window anchoring.

The invention incorporates a flat cable assembly that transmits electrical power from indoor to outdoor through a housing opening while still allowing the partially or complete closure of said housing opening. The flat cable assembly includes structural components to offer sufficient stiffness to hold the device securely on the housing opening. FIG. 5 and FIG. 6 illustrate the preferred embodiment of the invention. The flat cable assembly is installed over the door upper horizontal edge which acts has holding hook of both enclosures located indoor and outdoor. FIG. 5 illustrates the invention installed close to the door edge opening side, however by placing the device close to the door hinge side, that limits the obstruction of the device and then keeps the door opening ability.

The invention contains different features to facilitate its installation and at same time ensure a complete user electrical safety. The invention addresses the problem of passing electrical conductors through housing openings which can be consider as hazardous locations for standard electrical cords. The invention is especially designed to be installed on housing opening and provide safe temporary installation which getting its electrical power source from an indoor located outlet. The invention consists to install the electrical safety components before the house opening crossing section which is the risky and hazardous section. The invention incorporates typical EVSE electronic controller located in the indoor located enclosure. This EVSE controller validates proper EV connections before providing electrical power to the risky part of the system. One embodiment of the invention can incorporates turn on sequence integrity check which validates the flat wire assembly to test if any undesired damage was suffered by said flat wire assembly by the uses of physical damage sensor. This damage detection can be used as an additional safety feature added to typical EVSE safeties. More to that said turn on sequence integrity check, modified embodiment of the invention may incorporate construction inventive principle consisting of favoring a confined ground fault inside the said flat wire assembly. In case of damage occurring during operation, this confined ground fault will then latch the Ground Fault Circuit Interrupter (GFCI) protection of the EVSE controller before electrifying external components.

FIG. 5 and FIG. 6 illustrate the entire apparatus which form the preferred embodiment of the present invention specially designed for use on a housing door 30. So components positions in the system are not limited to the illustrated examples. The system is powered by an in-house located 208-240 V electrical outlet. The system comprises a male plug 34 which can be connected on typical extension cord compatible with the electrical plug model and gauge size in accordance with the electrical standards applied in the region of use. The supply cable 32 is connected to the EVSE control enclosure 7 and it is held by strain relief or other proper cable entry holding device 35. The EVSE control enclosure 7 and the secondary enclosure 8 are mechanically attached to the flat cable assembly 9. Both enclosure (7 and 8) are illustrated like plastic or metallic electrical box. However, they can be made by molding a complete part and then encapsulates all internal components inside. The flat cable assembly acts as suspending device to securely hold EVSE control enclosures 7 and the secondary enclosure 8 on the upper door edge. The secondary enclosure 8 ensures the back transition to EV supply cable 56 which is held by strain relief or other cable entry holding device 58. The EV supply cable 56 is a typical EV charging cable which comprising the live and ground wires and smaller gauge pilot wires. The last part of the system is a dedicated EV plug 33 compatible with the EV to be charged. The invention may be assembled with different types of EV plug or be combined to specific adaptor to match various EV types and models.

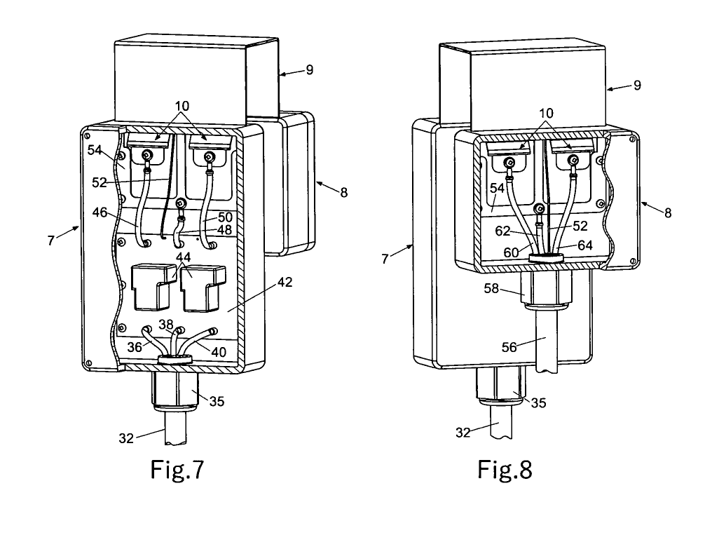

FIG. 7 illustrates one embodiment of internal component arrangement comprised into the EVSE control enclosure 7. The 208-240V supply live wires 36 and 40, of said supply cable 32, are connected to a state of the art or modified version of EVSE controller electronic circuit 42. The EVSE controller electronic circuit 42 comprises electrical disconnecting means 44 such as relays or contactors which provide the electrical contact between supply live wires 36, 40 and their respective output supply live wires 46 and 50. When all safety conditions are respected (from EVSE standard or additional safety check), electrical contact are closed between wires pairs (36, 46) and (40, 50) to supply the EV for charging. The output supply live wires 46 and 50 are electrically connected to a pair of specially design flat wire assemblies 10. These flat wire assemblies 10 go through channels inside the flat cable assembly 9.

In this embodiment, the ground wire 38 of the supply cable 32 is connected to the EVSE electronic controller circuit 42. On other embodiment, the ground wire can be connected on other grounding terminals of the EVSE control enclosure. In the disclosed embodiment of FIG. 7, the ground wire 38 is directly routed by the EVSE controller electronic circuit 42 to be electrically connected to the output grounding wire 48. In the preferred embodiment of the invention, the output grounding wire 48 is electrically connected to the inner metallic layer 54 of the flat cable assembly 9 in order to makes complete electrical grounding of flat cable assembly 9. The inner metallic layer 54 of the flat cable assembly 9 is mechanically attached to both enclosures to make a firm attachment. Depending on required signal for communication between the EVSE controller electronic and the EV to be charged, smaller gauge wire can go through channels of the flat cable assembly to make small signal connection from EVSE control enclosure 7 to the secondary enclosure 8. In the disclosed embodiment, the pilot wire 52 is connected to the EVSE controller electronic circuit and goes through the flat cable assembly.

FIG. 8 illustrates one embodiment of internal component arrangement comprised into the secondary enclosure 8. The other ends of flat wire assemblies 10 are electrically connected to supply wires 60 and 64 of the EV supply cable 56. The ground wire 62 of the EV supply cable 56 is electrically connected to the inner metallic layer 54 of the flat cable assembly 9. In this embodiment, the pilot wire 52 exits the flat cable assembly and goes into the EV supply cable.

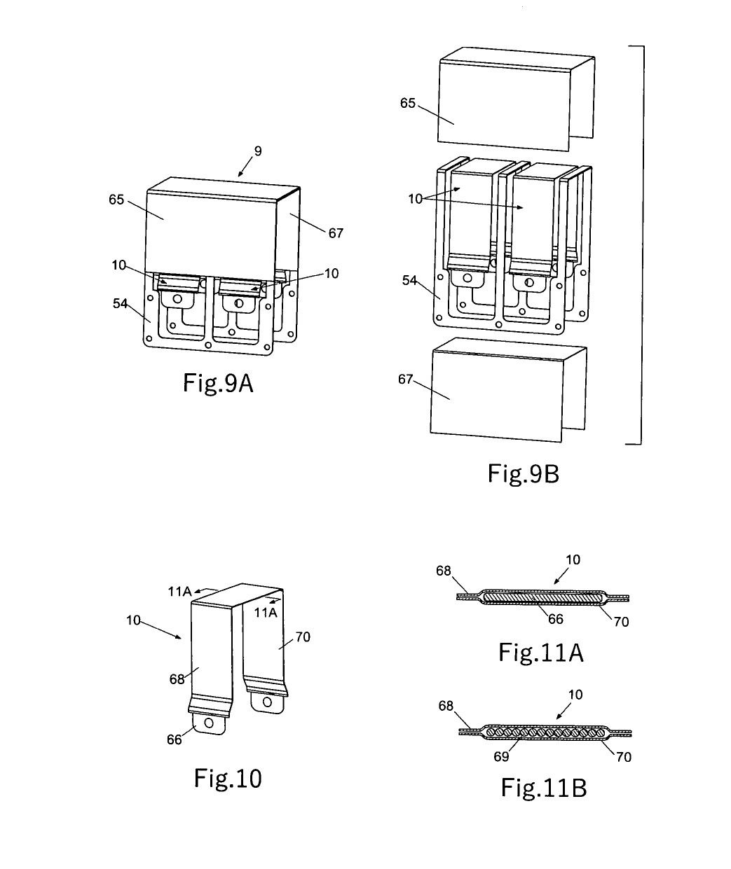

FIG. 9A and FIG. 9B illustrate assembled view and exploded view of the preferred embodiment of flat cable assembly 9. This embodiment of flat cable assembly is a rigid an armored version which is basically made with 3 metallic layers. It comprises a top metallic layer 65 and a bottom metallic layer 67. The flat cable assembly 9 contains an inner metallic layer 54 which is used to mechanically hold the indoor and outdoor located enclosure on both sides of the door and provides spacing between the top and bottom metallic layers. These layers are made with metallic material for proper grounding. They are preferably made of stainless steel for high mechanical and corrosion resistance. The uses of stainless steel can benefit from its laser welding ability which can ease its complete sealing and assembly by various welding technique. The inner metallic layer 54 is a single piece which having open section to creates channels for the flat wire assemblies 10. With proper joining mean of top 65, inner 54 and bottom 67 metallic layers, the complete flat cable assembly 9 provides a robust protection to the flat wire assemblies 10 and thanks to its metallic conception and by being electrically connected to ground, it provides a self electrical protection. The joining mean of layers can be such as welding, rivet, screws, glues or other available techniques.

FIG. 10 illustrates the flat wire assembly 10. The preferred embodiment of the invention uses simple version of flat wire assembly which consists of a flat live electrical conductor 66 made with metallic strip, surrounded by a top primary electrical isolation layer 68 and a bottom primary electrical isolation layer 70 which are made with electrical isolation material such as polyimide film or other material having high electrical dielectric isolation.

FIG. 11A illustrates a cross section view of the flat wire assembly 10. The flat live electrical conductor 66 transmits the electrical power from the EVSE control enclosure 7 to the secondary enclosure 8 for EV charging. The flat live electrical conductor 66 must have a sufficient cross section to support the current rating of the EVSE. The flat live electrical conductor 66 is preferably made of a single metal piece but it may also be made by a stack of thinner overlapped metal layers in a manner to offer better flexibility.

FIG. 11B illustrates a cross section view of modified embodiment of flat wire assembly 10. The flat live electrical conductor can be replaced by a set of single circular live electrical conductor 69 which all combined provide an equivalent electrical conductor cross section area. Like illustrated in FIG. 11B, circular live electrical conductor can be bound together with same top and bottom primary electrical isolation layers but they can also be an assembly comprising typical circular shape wire with electrical isolation coating.

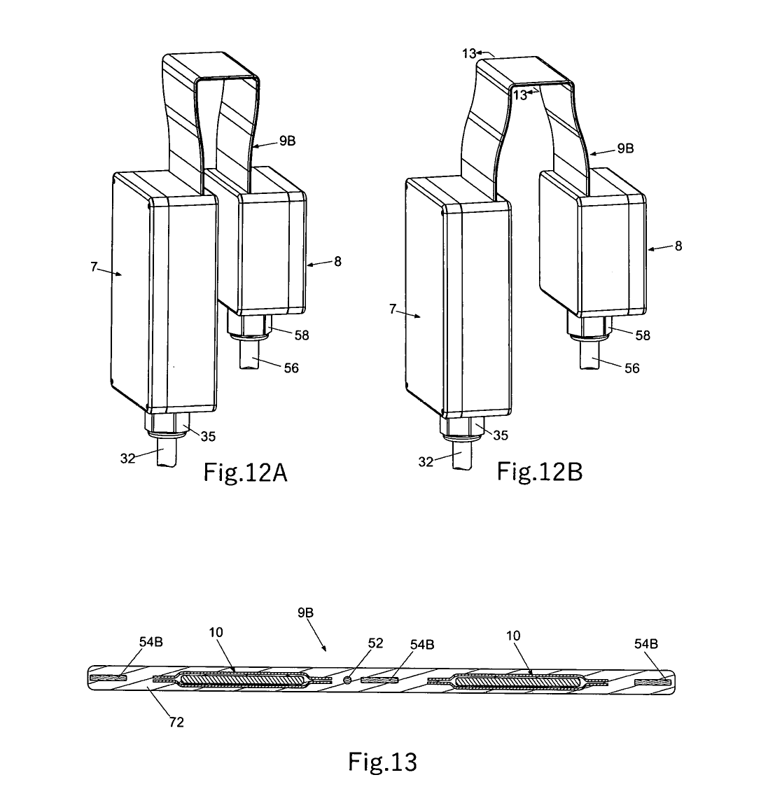

In the preferred embodiment, the flat cable assembly 9 is a rigid part. But in some modified embodiments, the flat cable assembly may be specially design for having flexibility to add more installation convenience or ease of transportation packaging. FIG. 12A and FIG. 12B illustrate modified embodiment which having a flexible flat cable assembly 9B when contracted or expanded.

FIG. 13 illustrates a cross section view of an embodiment of flexible flat cable assembly 9B. Instead of having top and bottom metallic layers for flat wire protection, the flexible flat cable assembly 9B can be made by molding standard polymer or plastic 72 used for cable manufacturing which encapsulates and comprising all sub components inside: inner layer for device holding capability 54B, flat wire assemblies 10 and other signal wire such as pilot wire 52. The inner layer for device holding 54B is used as part to mechanically attach the flexible flat cable assembly 9B to both enclosures 7 and 8. Depending on the flexibility and mechanical strength design parameter, the inner layer for device holding 54B may be a similar metallic version such is proposed for the inner metallic layer 54 or may be made of other more flexible material with proper strength and flexibility.

One inventive principle of the invention is to provide maximum electrical safety by protecting user from electrical hazard. In the preferred embodiment disclosed in FIG. 9A and FIG. 9B, the flat cable assembly is well protected by metallic shielding. The embodiment disclosed in FIG. 13 has flexibility but it does not offer the same level of mechanical and electrical safety due to the absence of metallic armored protection. To be more in respect to the inventive principle of the invention, the flat wire assembly 10 used in the embodiment disclosed in FIG. 13 may be a modified version to improve the electrical safeties.

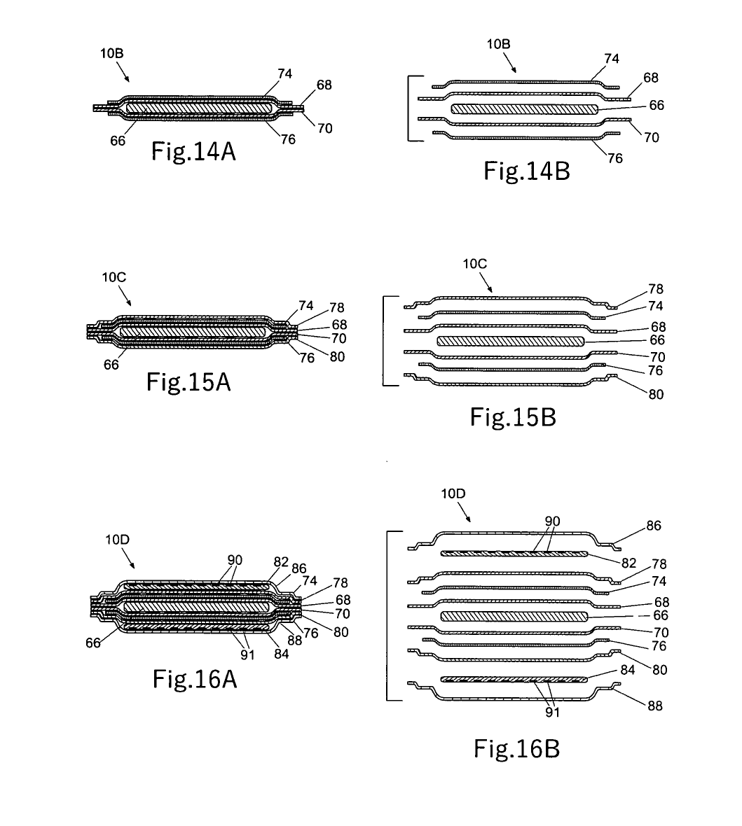

FIG. 14A and FIG. 14B illustrate cross section assembled and exploded view of one modified embodiment of flat wire assembly 10B. This embodiment has the flat live electrical conductor 66 surrounded by top and bottom primary electrical isolation layers 68 and 70. Compared to the embodiment 10, the embodiment 10B has additional top and bottom flat ground electrical conductors 74 and 76 also made with metallic strip. FIG. 14A shows that flat live electrical conductor 66 and flat ground electrical conductors 74 and 76 are spatially superimposed in the flat wire assembly 10B. This superimposed arrangement will favor electrical contact between the ground conductor and the live conductor if any damage from perforation occurs. Thanks to the GFCI implemented in the EVSE controller electronic circuit 42, by favoring the electrical contact between the live and ground conductor, that will automatically disconnect the electrical power from live conductor by opening the disconnection means 44 of the EVSE controller electronic 42 and consequently protect the EVSE user.

FIG. 15A and FIG. 15B illustrate cross section assembled and exploded view of one modified embodiment of flat wire assembly 100. This embodiment contains all same components than embodiment 10B. However, it contains additional top and bottom secondary electrical isolation layers 78 and 80 for additional electrical isolation.

This stacking of flat ground electrical conductors 74 and 76 surrounding the live flat conductor 66 is a main inventive principle of the invention that favors a confined ground fault in case of flat cable assembly damage or perforation.

One major principle of this invention is to provide a maximum electrical safety and at same time ease of use. For some reason the flexible embodiment of flat cable assembly illustrated in FIG. 13 may offer more flexibility which add ease of use with a cost of electrical safety diminution compared to the preferred embodiment illustrated in FIG. 9A and FIG. 9B. The electrical safety of flat wire assembly 10B and 100 rely on the GFCI implemented in the EVSE controller circuit. To engage the GFCI protection detection, electrical power has to be applied on the live conductor to detect the ground fault current. In addition to the GFCI, some previous detection can be implemented in the EVSE controller circuit 42 to measure the electrical impedance between the ground conductors 74 and 76 relative to the metallic strip conductor 66 before applying the high voltage power. In addition to these safeties, special implementation of flat wire assembly can provide a self detection system to detect if the flat wire assembly has any damage.

FIG. 16A and FIG. 16B illustrate cross section assembled and exploded view of another embodiment of flat wire assembly 10D which comprising a specially designed damage sensing ability. This embodiment contains all same components than embodiment 10C but it may be combined to other disclosed embodiment of flat wire assembly. This embodiment has additional specific top and bottom damage sensors layers 82 and 84 which comprise small gauge electrical serpentine pattern 90 and 91. The damage sensor layers 82 and 84 may be made with flex printed circuit board technology to form the small gauge electrical patterns 90 and 91 with small electrical trace which having a dense serpentine pattern. The serpentine pattern may also be made with small gauge wire assembled into pair of isolation material. To protect these additional layers, another set of top and bottom tertiary electrical isolation layers 86 and 88 are added to the stack.

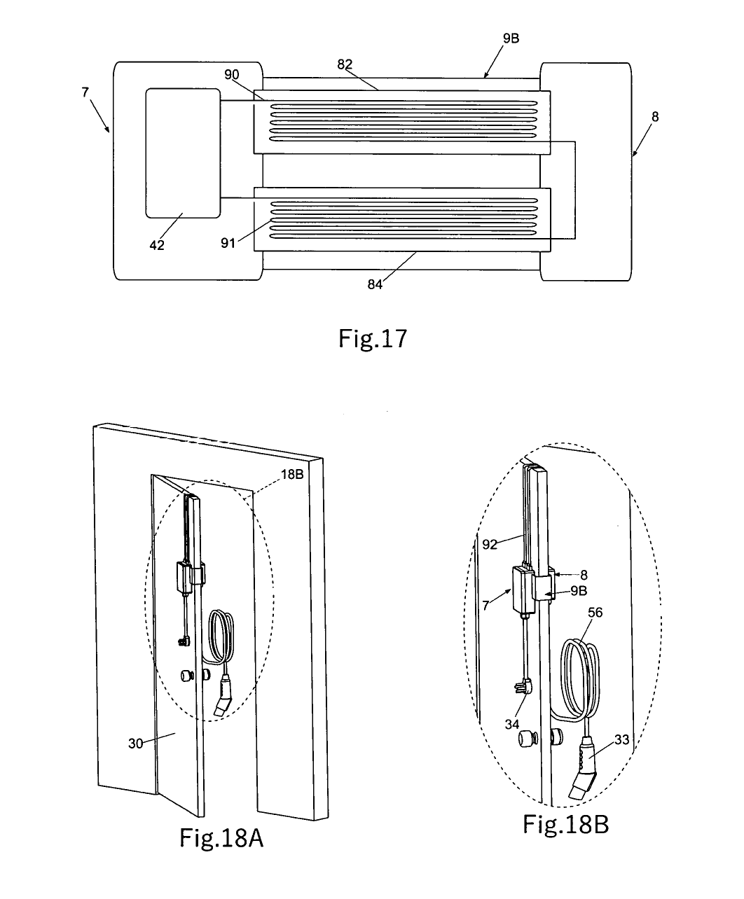

FIG. 17 illustrates a diagram of the electrical connection of the damage sensing circuit. The top and bottom damage sensor layer 82 and 84 are illustrated for only one flat wire assembly but in the invention which comprising this damage sensor system, both flat wire assemblies will have its own damage sensor layer pair. The EVSE controller electronic circuit 42 is connected on one end of the small gauge electrical serpentine pattern 90 of the top damage sensor layer 82. The electrical connection between the small gauge electrical serpentine pattern 90 of the top damage sensor layer 82 and the small gauge electrical serpentine pattern 91 of the bottom damage sensor layer 84 is made in the secondary enclosure 8. This loop backs the electrical connection from and to the EVSE control electronic circuit 42. The EVSE control electronic circuit 42 can validates the physical integrity of the corresponding flat wire assembly by monitoring the electrical connectivity continuity between the top damage sensor layer 82 and bottom damage sensor layer 84. If the flat wire assembly is damaged near the flat live electrical conductor 66, the top 82 or bottom 84 damage sensor layers will be damaged at the same time that will obligatory damage one of the serpentine pattern. Consequently, that will open the electrical circuit illustrated in FIG. 17. This monitoring system offer the capability to test the physical integrity before applying electrical power on live conductor and keep tracking while live conductor are electrically powered.

The preferred embodiment is to anchor the device over the top horizontal edge of housing door with the flat cable assembly 9. FIG. 18A and FIG. 18B illustrate an alternative embodiment which is still in the spirit of the invention. The flexible flat cable assembly 9B passes the housing opening on the vertical edge of the housing door, preferably on the edge that is opposite to the door hinges. The EVSE control enclosure 7 and secondary enclosure 8 are still held using holding bands 92 located on the top horizontal door edge. By the uses of adjustable length holding bands, this embodiment can be adapted to be installed on other type of house opening such has casement windows.

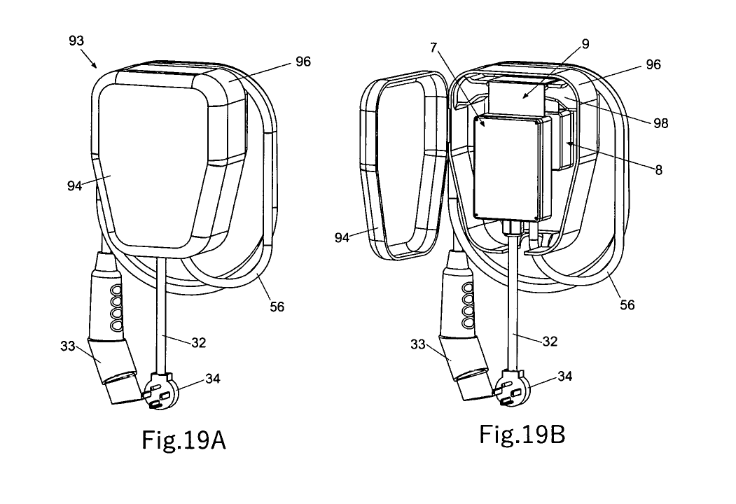

The invention mostly addresses the problematic of EV charging at destination site. However, the proposed EVSE invention is not only limited for destination use. FIG. 19A and FIG. 19B illustrate the invention combined to an additional holding enclosure 93. The holding enclosure 93 is especially designed to be installed at the EV owner parking location where outside located 208-240 V outlet has been installed. The holding enclosure comprises back piece 96 which has internal holding component 98 to attach and hold the EVSE invention when stored in the holding enclosure. The holding enclosure 93 also has a front cover 94 which closes the holding enclosure to confine and protect the EVSE invention inside. The back piece 96 preferably has a shape to provide winding support of the EV supply cable 56. The combination of the EVSE invention and this holding enclosure makes the proposed invention has a solution which can replace conventional EVSE system installed at the EV owner residence parking space for general use for daily charging.

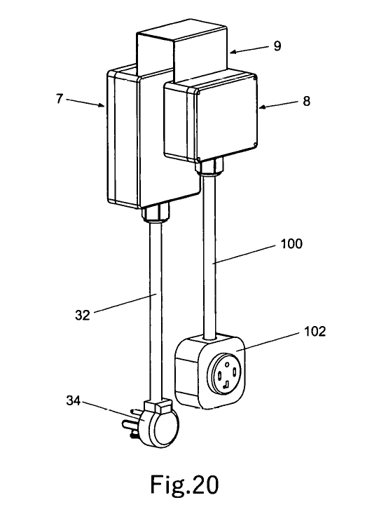

The preferred embodiment of the invention comprises a complete solution which can be directly connected to EV for charging. FIG. 20 illustrates a modified embodiment which can be used in combination with state of the art portable EVSE. In this embodiment, the invention is still electrically powered front an indoor located electrical outlet. Compared to traditional extension cord, the invention provides electrical safeties to protect the hazardous house opening section and can comprise a control electronic to validate if there is no ground fault or check the physical integrity of the flat wires before providing electrical power. In this embodiment, the EV supply cable 56 is replaced by EVSE supply cable 100 connected to an electrical female outlet 102. Portable EVSE can therefore be connected on the outdoor located protected female outlet 102.

While a preferred embodiment and alternative embodiments have been shown and described, it should be understood that a number of changes and modifications are possible therein. Accordingly it is to be understood that there is no intention to limit the invention to the precise constructions disclosed herein, and the right is reserved to all changes and modifications coming within the scope of the invention as defined in the appended claims.

What is claimed is:

1. An apparatus for electric vehicle recharging comprising:
a means for powering electrically which receiving its electrical power from indoor located electrical outlet;
a first means for encapsulating which comprising inside at least one means for disconnecting electrical power which receive electrical power from said means for powering electrically;
a means for detecting predetermined safe conditions which control the closure of said means for disconnecting electrical power;
a flat cable assembly having its first end mechanically bound to said first means for encapsulating and receiving electrical power from said means for disconnecting electrical power;
a means for anchoring firmly and securely the apparatus on house opening component;
a second means for encapsulating which is mechanically bound to the second end of said flat cable assembly;
an electric vehicle supply cable mechanically bound to said second means for encapsulating and receive electrical power from said flat cable assembly;
whereby electrical vehicle recharging from an indoor located electrical outlet is feasible securely by temporary installing the apparatus on housing opening components.

2. Flat cable assembly of claim 1 having capability of being installed through a closed housing opening.

3. Flat cable assembly of claim 1 further comprising pluralities of flat wire assembly and smaller gauge wire for device communication.

4. Flat wire assembly of claim 3 wherein electrical live conductor can be made with plurality of flattened shape metallic electrical conductor.

5. Flat wire assembly of claim 3 wherein electrical live conductor can be made with plurality of circular shape metallic electrical conductor.

6. Flat cable assembly of claim 1 having rigid structure for providing protection to said flat wire assembly.

7. Flat cable assembly of claim 1 having rigid structure for providing apparatus holding capability and becoming said means for anchoring.

8. Flat cable assembly of claim 1 having flexible structure made with flexible material to provide flexible version of said flat cable assembly.

9. Electric vehicle supply cable of claim 1 can be replaced by EVSE supply cable and female electrical outlet.

10. A flat wire assembly comprising:
a flattened live electrical conductor;
a plurality of electrical isolation layer providing electrical isolation on top and bottom to said flattened live electrical conductor;
a first stack made by assembling said electrical isolation layers on top and bottom side of said flattened live electrical conductor;
a first damage detection layer having a thin metallic pattern;
a second damage detection layer having a thin metallic pattern;
a second stack made by assembling said first and second damage detection layer on top and bottom of said first stack;
a means for measuring electrical continuity;
whereby damage of flat wire assembly can be detected by probing the electrical continuity of thin metallic pattern with said means for measuring electrical continuity.

11. Damage detection layer of claim 10 is made with flex printed circuit board technology.

12. Thin metallic pattern of claim 10 is made with small gauge electrical wire.

13. A device to protect and hold securely the electric vehicle recharging system comprising:
a first enclosure piece in which said electric vehicle recharging system can be introduced for proper holding;
a second enclosure piece to close the entire device;
whereby said electric vehicle recharging system can be installed in the device to protect permanently the electric vehicle recharging system at the owner parking space for daily charging.

14. First enclosure piece of claim 13 having specific shape for providing support to said electric vehicle supply cable.
